(19) United States
(12) Patent Application Publication
(10) Pub. No.: US 2026/0083004 A1
(43) Pub. Date: Mar. 19, 2026

(54) CHIP PACKAGING METHOD AND SEMICONDUCTOR PACKAGE STRUCTURE

(71) Applicant: WUHAN XINXIN SEMICONDUCTOR MANUFACTURING CO., LTD., Wuhan (CN)

(72) Inventors: Guoliang YE, Wuhan (CN); Jun ZHOU, Wuhan (CN); Qiong ZHAN, Wuhan (CN); Sheng HU, Wuhan (CN); Changbao ZHAO, Wuhan (CN)

(21) Appl. No.: 19/108,673

(22) PCT Filed: Nov. 24, 2022
(86) PCT No.: PCT/CN2022/133926

§ 371 Date: Mar. 4, 2025

(30) Foreign Application Priority Data
Sep. 27, 2022 (CN) 202211184755.2

(51) Int. Cl. H01L 25/18; H01L 23/00; H01L 23/522; H10D 1/68

(52) U.S. Cl. CPC H10W 90/00; H10D 1/714; H10D 1/716; H10W 20/42; H10W 80/312; H10W 80/327

(57) ABSTRACT

The present invention relates to a chip packaging method and a semiconductor package structure. In the method, at least one effective die and at least one DTC die are bonded to a surface of a first device substrate at one side thereof, respectively, through bonding, the effective die is electrically connected to an electronic component in the first device substrate. The DTC die allows the surface of the first device substrate that is not occupied by the effective die to be fully utilized This helps increase both an integration density and a capacitance density of the resulting semiconductor package structure, increase its high-frequency signal stability and improve its performance. The semiconductor package structure is formed according to the above chip packaging method.

### TECHNICAL FIELD

The present invention relates to the field of semiconductor technology and, in particular, to a chip packaging method and a semiconductor package structure.

### BACKGROUND

Chip-to-wafer (C2W) technology is globally popular among semiconductor manufacturers because it is not limited by chip size matching and its known good dies (KGD) solution can greatly increase yield.

In an advanced packaging process, the effective dies are bonded to a device substrate and the dummy dies are bonded in the gaps of the device substrate by using C2W technology. Additionally, another device substrate may be bonded to the effective dies and dummy dies. As needed, a semiconductor package structure is obtained by vertically dicing of the device substrate and removing unnecessary portions. Configuration of the dummy dies can ensure bonding area and guarantee desirable bonding strength. However, this fails to make full use of the substrate's surface area. Consequently, the resulting semiconductor package structure has a relatively low integration density, and still further improvements would be desirable in their performance.

### SUMMARY OF THE INVENTION

In order to make full use of the surface area of a substrate and to improve performance of a semiconductor package structure, the present invention provides a chip packaging method and also a semiconductor package structure.

In one aspect, the present invention provides a chip packaging method, comprising:
providing a first device substrate, wherein an electronic component is formed in the first device substrate; and
bonding at least one effective die and at least one DTC die to a surface of the first device substrate at one side thereof, wherein through bonding, the effective die is electrically connected to the electronic component in the first device substrate.

Optionally, the chip packaging method may further comprise:
forming a filler material in a gap between the effective die and the DTC die;
forming an interlayer dielectric layer, wherein the interlayer dielectric layer covers the effective die and the DTC die; and
forming a metal interconnect layer on the interlayer dielectric layer, which is electrically connected to the effective die by a contact plug extending through the interlayer dielectric layer.

Optionally, the chip packaging method may further comprise:
forming a bonding layer on the metal interconnect layer; and
bonding a second device through the bonding layer, an electronic component is formed in the second device substrate, wherein through bonding, the electronic component in the second device substrate is electrically connected to the effective die.

Optionally, the chip packaging method may further comprise: stacking another DTC die above the effective die and/or the DTC die.

Optionally, the effective die and/or the DTC die may be bonded to the first device substrate by micro-bump bonding or hybrid bonding.

Optionally, at least one DTC may be formed on the surface of the first device substrate.

Optionally, at least a portion of the DTC dies are bonded to the DTCs and are connected in parallel with corresponding DTC.

Optionally, a proportion of an area where the effective dies are bonded on the surface of the first device substrate 100 is less than or equal to 50-85%.

In another aspect, the present invention provides a semiconductor package structure comprising:
a first device substrate, wherein an electronic component is formed in the first device substrate; and
at least one effective die and at least one DTC die, which are bonded to a surface of the first device substrate at one side thereof, wherein through bonding, the effective die is electrically connected to the electronic component in the first device substrate.

Optionally, the semiconductor package structure may further comprise:
an interlayer dielectric layer covering the effective die and the DTC die;
a metal interconnect layer, wherein the metal interconnect layer is located on the interlayer dielectric layer and is electrically connected to the effective die by a contact plug extending through the interlayer dielectric layer;
a bonding layer located on the metal interconnect layer; and
a second device substrate bonded to the first device substrate by the bonding layer, wherein an electronic component is formed in the second device substrate, and wherein through bonding, the electronic component in the second device substrate is electrically connected to the effective die.

In the chip packaging method and semiconductor package structure of the present invention, at least one effective die and at least one DTC die are bonded to a surface of a first device substrate at one side thereof, respectively. Through bonding, the effective die is electrically connected to an electronic component in the first device substrate. The DTC die allows the surface of the first device substrate that is not occupied by the effective die to be fully utilized. This helps increase both an integration density and a capacitance density of the resulting semiconductor package structure, increase its high-frequency signal stability and improve its performance.

### BRIEF DESCRIPTION OF THE DRAWINGS

FIG. 1 is a schematic cross-sectional view of a DTC die and DTCs according to an embodiment of the present invention.

FIG. 2 is a flowchart of a method for packaging a die according to embodiments of the present invention.

FIGS. 3A to 3F are schematic cross-sectional views of structures resulting from steps in a method for packaging a die according to an embodiment of the present invention.

### LIST OF REFERENCE NUMERALS

101—first trench; 102—second trench; 103—first dielectric layer; 104—first conductive layer; 104a—first conductive plug; 105—second dielectric layer; 106—second conductive layer; 106a—second conductive plug; 107—oxide layer; 108—interlayer dielectric layer; 100—first device substrate; 110—DTC; 120—effective die; 130—DTC die; 140—filler material; 150—interlayer dielectric layer; 151—contact plug; 160—metal interconnect layer; 170—bonding layer; 200—second device substrate.

### DETAILED DESCRIPTION

A chip packaging method and a semiconductor package structure according to specific embodiments of the present invention will be described in greater detail below with reference to the accompanying drawings. From the following description, advantages and features of the present invention will be more apparent. It will be understood that the figures are provided in a very simplified form not necessarily drawn to exact scale for the only purpose of helping to explain the disclosed embodiments in a more convenient and clearer way.

It is noted that the terms “first”, “second” and the like may be used herein to distinguish between similar elements without necessarily implying any particular ordinal or chronological sequence. It will be understood that the terms so used are interchangeable, whenever appropriate, such that, for example, the embodiments of the invention described herein are capable of operation in sequences other than those illustrated or otherwise described herein. Likewise, if a method is described herein as comprising a series of steps, the order of these steps as presented herein is not necessarily the only order in which they can be performed, and certain ones of the stated steps may be possibly omitted and/or certain other steps not described herein may be possibly added to the method.

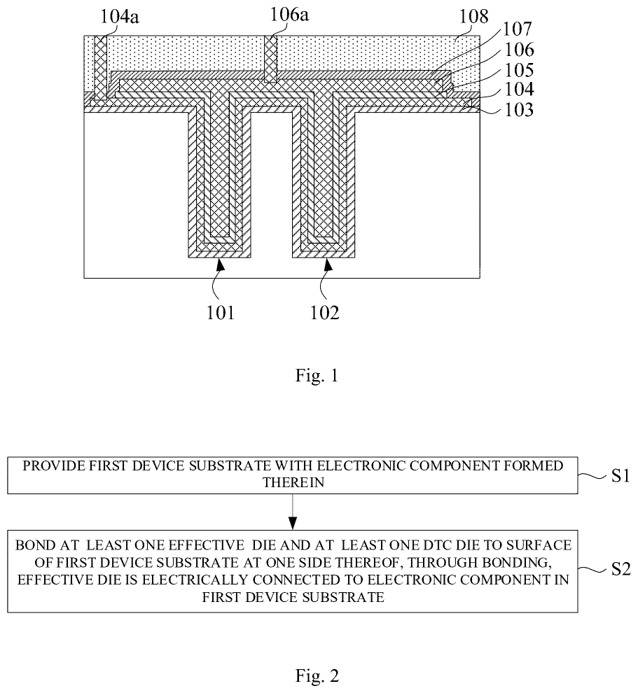

A chip packaging method and a semiconductor package structure according to embodiments of the present invention involve the deep trench capacitor (DTC) formed in trench of a semiconductor substrate. Compared with some other types of capacitors in semiconductor integrated circuit, such DTC exhibits a higher power density. FIG. 1 shows a schematic cross-sectional view of a DTC die and DTC according to an embodiment of the present invention. However, it will be understood that DTC die and DTC according to embodiments of the present invention are not limited to be structured as shown FIG. 1, as many other structures are possible.

Referring to FIG. 1, according to an exemplary embodiment, the DTC die and DTC may include:
a first trench 101 and a second trench 102 formed in a substrate;
a first dielectric layer 103 lining inner walls of the first trench 101 and the second trench 102 and covering a surface of the substrate, the first dielectric layer 103 optionally including at least one of silicon oxide, silicon nitride and silicon oxynitride;
a first conductive layer 104 deposited on the first dielectric layer 103, the first conductive layer 104 optionally including doped polysilicon;
a second dielectric layer 105 deposited on the first conductive layer 104, the second dielectric layer 105 optionally including at least one of silicon oxide, silicon nitride and silicon oxynitride;
a second conductive layer 106 deposited on the second dielectric layer 105 and filling remaining gaps in the first trench 101 and the second trench 102, the second conductive layer 106 optionally including doped polysilicon, the second dielectric layer 105 sandwiched between the first conductive layer 104 and the second conductive layer 106 and separating them from each other; and
an oxide layer 107 and an interlayer dielectric layer 108 stacked on the oxide layer, wherein within the interlayer dielectric layer 108, a first conductive plug 104a connected to the first conductive layer 104 and a second conductive plug 106a connected to the second conductive layer 106 are formed.

A chip packaging method according to an embodiment of the present invention includes the steps as follow.

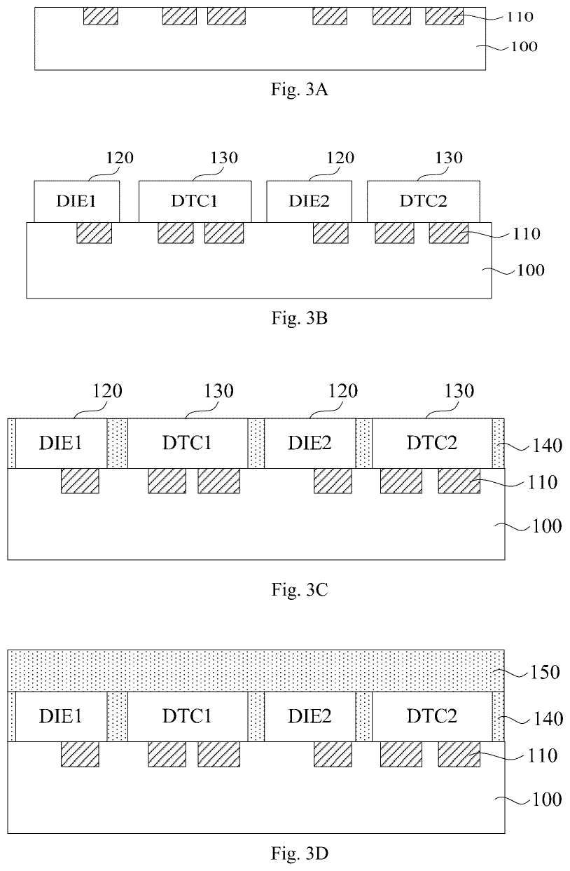

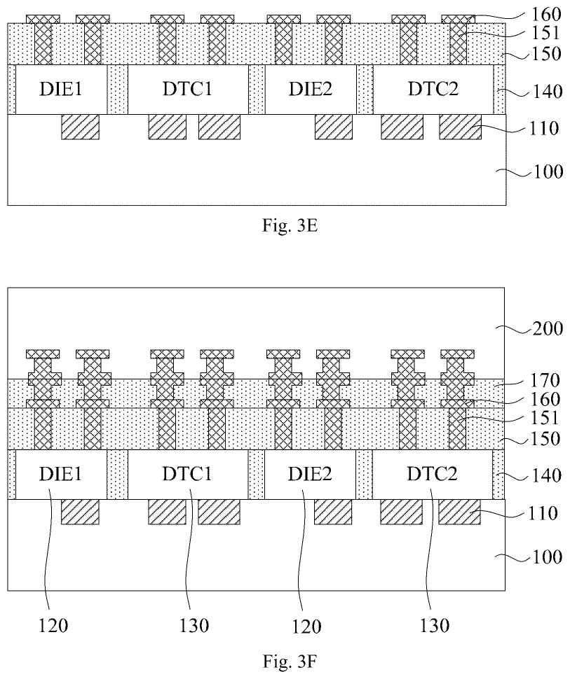

FIG. 3A is a schematic cross-sectional view of a first device substrate provided in the chip packaging method according to an embodiment of the present invention. Referring to FIGS. 2 and 3A, first of all, in step S1, a first device substrate 100 with electronic component formed therein is provided.

For example, the first device substrate 100 may be a silicon wafer, and the electronic component formed in the first device substrate 100 may include at least one of MOS device, sensor device, memory device and passive device. The sensor device may be light-sensing device or the like, and the memory device may include non-volatile memory (NVM) device, random access memory (RAM) device, etc. The NVM device may include floating gate memory device such as NOR, NAND or similar flash memory device, ferroelectric memory device, phase change memory device, etc. The passive device may include resistor, capacitor or the like. The electronic component may be planar or three-dimensional (3D) device. The 3D device may be fin field-effect transistor (FinFET), 3D memory or other device. The electronic component may be covered by a dielectric material. The dielectric material may be a stack of layers and may include silicon oxide, silicon nitride, silicon oxynitride or the like. In this embodiment, at least a portion of the electronic components are intended to be connected to effective dies bonded to the first device substrate.

In this embodiment, at least one DTC 110 is formed on the surface of the first device substrate 100. The DTC 110 can improve the capacitance density in the semiconductor package structure containing the DTC 110. The DTC 110 is, for example, isolated from those of the electronic components in the first device substrate 100 that are intended to be connected to effective dies.

FIG. 3B is a schematic cross-sectional view of a structure resulting from the chip packaging method after bonding an effective die and a DTC die to a surface of a first device substrate according to an embodiment of the present invention.

Referring to FIGS. 2 and 3B, in step S2, at least one effective die 120 (e.g., DIE1 and DIE2 of FIG. 3B) and at least one DTC die 130 (e.g., DTC1 and DTC2 of FIG. 3B) are bonded to a surface of the first device substrate 100 at one side thereof, respectively. Through bonding, the effective die 120 is electrically connected to an electronic component in the first device substrate 110.

The DTC die 130 is arranged on the surface of the first device substrate 100 where the effective die 120 is not bonded. The electrode terminals of the DTC die 130 may be facing toward or away from the first device substrate 100 during bonding. In this embodiment, the electrode terminals of the DTC die 130 all face toward the first device substrate 100. The effective die 120 and/or the DTC die 130 may be bonded to the first device substrate 100 by micro-bump bonding or hybrid bonding.

In some embodiments, at least a portion of DTC dies 130 are bonded to DTCs 110 on the surface of the first device substrate 100, and are connected in parallel with corresponding DTCs 110. This can additionally increase the capacitance density of the resulting semiconductor package structure.

The quantity and position of the DTC dies 130 bonded to the surface of the first device substrate 100 can be adjusted as needed. In preferred embodiments, the surface of the first device substrate 100, where effective die 120 is not bonded, can be fully utilized by bonding DTC dies 130. For example, on the surface of the first device substrate 100, the proportion of an area where all the effective dies are bonded is less than or equal to 50-85%, that is, 15% to 50% of the surface area of the first device substrate 100 has not yet been occupied by the effective dies 120. DTC dies 130 may be bonded to the first device substrate 100 corresponding to the gaps between adjacent effective dies 120. This not only does not affect the bonding effect of the effective dies 120, but also fully utilizes the surface of the first device substrate 100 where effective dies are not bonded. Therefore, compared to the use of dummy dies, the resulting semiconductor package structure will have an increased integration density, a higher capacitance density, improved high-frequency signal stability and a more uniform coefficient of thermal expansion, thus exhibiting enhanced performance.

FIG. 3C is a schematic cross-sectional view of a structure resulting from the chip packaging method after forming a filler material according to an embodiment of the present invention. FIG. 3D is a schematic cross-sectional view of a structure resulting from the chip packaging method after forming an interlayer dielectric layer according to an embodiment of the present invention. FIG. 3E is a schematic cross-sectional view of a structure resulting from the chip packaging method after forming a metal interconnect layer according to an embodiment of the present invention. Referring to FIGS. 3C to 3E, the method may further include the steps as follows.

As shown in FIG. 3C, a filler material 140 is formed between the effective die 120 and the DTC die 130. Specifically, the filler material may be deposited between, and on top surfaces of, the effective die 120 and the DTC die 130. The filler material 140 may include silicon oxide, silicon nitride, silicon oxynitride or another suitable material. A planarization (e.g., chemical mechanical polishing (CMP)) process may be then carried out to remove the filler material deposited above the dies. In this embodiment, bonding the DTC die 130 to a surface of the first device substrate 100, where effective dies 120 are not bonded, can facilitate performance of the planarization process.

Next, as shown in FIG. 3D, an interlayer dielectric layer 150 is formed, which covers the effective die 120 and the DTC die 130.

Subsequently, as shown in FIG. 3E, a metal interconnect layer 160 is formed on the interlayer dielectric layer 150. Additionally, a contact plug 151 may be formed, which extends through the interlayer dielectric layer 150 and electrically connects the metal interconnect layer 160 to the effective die 120. In this step, one or more interlayer dielectric layers 150 and metal interconnect layers 160 may be formed on the effective die 120 and the DTC die 130.

Before or after the interlayer dielectric layer 150 is formed, another DTC die may be optionally stacked on the effective die 120 and/or the DTC die 130, which can be electrically connected to, or insulated from, the underlying effective die 120 and/or DTC die 130.

FIG. 3F is a schematic cross-sectional view of a structure resulting from the chip packaging method after bonding a second device substrate to the first device substrate according to an embodiment of the present invention. Referring to FIG. 3F, in this embodiment, the method may further include the steps of: forming a bonding layer 170 on the metal interconnect layer 160; and bonding a second device substrate 200 to the bonding layer 170.

The bonding layer 170 formed on the metal interconnect layer 160 may include a dielectric layer and at least one bond pad that is embedded in the dielectric layer and electrically connected to the metal interconnect layer 160. Optionally, before bonding with the second device substrate 200, a metal interconnect layer 160 and at least one bond pad connected thereto may be formed above the DTC die 130 on the first device substrate 100.

For example, the second device substrate 200 may be a silicon wafer, in which electronic component may be formed. The electronic component in the second device substrate 200 may include at least one of MOS device, sensor device, memory device and passive device. A bond pad may be formed at a surface of the second device substrate 200 facing toward the first device substrate 100. The second device substrate 200 may be bonded to the bonding layer 170 by hybrid bonding so that the bond pad in the bonding layer 170 is connected to the bond pad at the surface of the second device substrate 200. Through the bonding process, an electronic component in the second device substrate 200 may be connected to the effective die 120 on the first device substrate 100 (e.g., via the bond pad and metal interconnect layer 160 as discussed above). In this bonding process, both the DTC die 130 and the effective die 120 are bonded to the second device substrate 200. This can ensure a sufficient bonding area of the first device substrate 100 and the second device substrate 200, which enables the first device substrate 100 and the second device substrate 200 to be bonded with sufficient strength.

After the second device substrate 200 is bonded to the bonding layer 170, a dicing process may be performed in the method to form a semiconductor package structure including at least part of the first bonding substrate 100, one or more effective dies 120, one or more DTC dies 130 and part of the second bonding substrate 200.

Embodiments of the present invention also provide a semiconductor package structure obtainable according to the method as discussed above. Referring to FIG. 3F, the semiconductor package structure includes: a first device substrate 100; at least one effective die 120 and at least one DTC die 130, bonded to a surface of the first device substrate 100 at one side thereof. The first device substrate 100 is formed with an electronic component, which is electrically connected to the effective die 120 through bonding.

Optionally, the effective die 120 and the DTC die 130 may be bonded to the first device substrate 100 by micro-bump bonding or hybrid bonding. In addition, the proportion of the bonding area of all the effective dies 120 bonded to the surface of the first device substrate 100 is, for example, less than or equal to 50-85%.

In some embodiments, at least one DTC 110 may be formed on the surface of the first device substrate 100, and at least one DTC die 130 may be bonded to the DTC 110 and connected in parallel with the DTC 110.

Referring to FIG. 3F, the semiconductor package structure may further include:
an interlayer dielectric layer 150 covering the effective die 120 and the DTC die 130;
a metal interconnect layer 160, which is located on the interlayer dielectric layer 150 and is electrically connected to the effective die 120 by a contact plug 151 extending through the interlayer dielectric layer 160;
a bonding layer 170 located on the metal interconnect layer 160; and
a second device substrate 200, which is bonded to the first device substrate 100 by the bonding layer 170 and are formed with at least one electronic component electrically connected to the effective die 120 through bonding.

In the semiconductor package structure of present invention, the at least one effective die 120 and the at least one DTC die 130 are bonded to the surface of the first device substrate 100, and through bonding, an electronic component in the first device substrate 100 is electrically connected to the effective die 120. The DTC die 130 is bonded to a surface of the first device substrate 100 where no effective die 120 is bonded, allowing for full utilization of the surface area of the first device substrate 100. This helps increase both an integration density and a capacitance density of the resulting semiconductor package structure, increase its high-frequency signal stability and improve its performance. Moreover, the DTC die 130 can increase surface planarity of a filler material resulting from a CMP process, enables the semiconductor package structure to have a more uniform coefficient of thermal expansion, and ensures sufficient bonding strength of the first device substrate 100 and the second device substrate 200. All these help improve the performance of the semiconductor package structure.

It is noted that the embodiments disclosed herein are described in a progressive manner, with the description of each embodiment focusing on its differences from others. Cross-reference can be made between the embodiments for their common or similar features.

While the invention has been described above with reference to several preferred embodiments, it is not intended to be limited to these embodiments in any way. In light of the teachings hereinabove, any person of skill in the art may make various possible variations and changes to the disclosed embodiments without departing from the scope of the invention. Accordingly, any and all such simple variations, equivalent alternatives and modifications made to the foregoing embodiments without departing from the scope of the invention are intended to fall within the scope thereof.

1. A chip packaging method, comprising:
providing a first device substrate, wherein an electronic component is formed in the first device substrate; and
bonding at least one effective die and at least one deep trench capacitor (DTC) die to a surface of the first device substrate at one side thereof, respectively, wherein through bonding, the effective die is electrically connected to the electronic component in the first device substrate.

2. The chip packaging method of claim 1, further comprising:
forming a filler material in a gap between the effective die and the DTC die;
forming an interlayer dielectric layer, wherein the interlayer dielectric layer covers the effective die and the DTC die; and
forming a metal interconnect layer on the interlayer dielectric layer, wherein the metal interconnect layer is electrically connected to the effective die by a contact plug extending through the interlayer dielectric layer.

3. The chip packaging method of claim 2, further comprising:
forming a bonding layer on the metal interconnect layer; and
bonding a second device substrate through the bonding layer, wherein an electronic component is formed in the second device substrate, and wherein through bonding, the electronic component in the second device substrate is electrically connected to the effective die.

4. The chip packaging method of claim 1, further comprising:
stacking another DTC die above the effective die and/or the DTC die.

5. The chip packaging method of claim 1, wherein the effective die and/or the DTC die is/are bonded to the first device substrate by micro-bump bonding or hybrid bonding.

6. The chip packaging method of claim 1, wherein at least one DTC is formed on the surface of the first device substrate.

7. The chip packaging method of claim 6, wherein at least a portion of the DTC dies are bonded to the DTCs and are connected in parallel with corresponding DTC.

8. The chip packaging method of claim 1, wherein a proportion of an area where the effective dies are bonded on the surface of the first device substrate 100 is less than or equal to 50-85%.

9. A semiconductor package structure, comprising:
a first device substrate, wherein an electronic component is formed in the first device substrate; and
at least one effective die and at least one deep trench capacitor (DTC) die, which are bonded to a surface of the first device substrate at one side thereof, wherein through bonding, the effective die is electrically connected to the electronic component in the first device substrate.

10. The semiconductor package structure of claim 9, further comprising:
an interlayer dielectric layer, wherein the interlayer dielectric layer covers the effective die and the DTC die;
a metal interconnect layer, wherein the metal interconnect layer is located on the interlayer dielectric layer and is electrically connected to the effective die by a contact plug extending through the interlayer dielectric layer;
a bonding layer located on the metal interconnect layer; and
a second device substrate bonded to the first device substrate by the bonding layer, wherein an electronic component is formed in the second device substrate, and wherein through bonding, the electronic component in the second device substrate is electrically connected to the effective die.

11. The semiconductor package structure of claim 9, wherein the effective die and/or the DTC die is/are bonded to the first device substrate by micro-bump bonding or hybrid bonding.

12. The semiconductor package structure of claim 9, wherein at least one DTC is formed on the surface of the first device substrate.

13. The semiconductor package structure of claim 12, wherein at least a portion of the DTC dies are bonded to the DTCs and are connected in parallel with corresponding DTC.

14. The semiconductor package structure of claim 12, wherein a proportion of an area where the effective dies are bonded on the surface of the first device substrate 100 is less than or equal to 50-85%.
